(19) United States
(12) Patent Application Publication
(10) Pub. No.: US 2020/0308447 A1
(43) Pub. Date: Oct. 1, 2020

(54) COMPOSITIONS FOR POLISHING COBALT AND LOW-K MATERIAL SURFACES

(71) Applicant: FUJIMI CORPORATION, Tualatin, OR (US)

(72) Inventors: Hooi-Sung KIM, Tualatin, OR (US); Charles POUTASSE, Tualatin, OR (US)

(73) Assignee: FUJIMI CORPORATION, Tualatin, OR (US)

(21) Appl. No.: 16/539,600

(22) Filed: Aug. 13, 2019

Related U.S. Application Data
(63) Continuation-in-part of application No. 16/369,193, filed on Mar. 29, 2019.

(51) Int. Cl. C09G 1/02; H01L 21/306

(52) U.S. Cl. CPC C09G 1/02; H01L 21/30625

(57) ABSTRACT

Provided herein are compositions and methods for polishing surfaces comprising cobalt and optionally a low-K material, e.g., in semiconductor device fabrication. Also provided herein are compositions and methods for polishing surfaces comprising a metal and/or silicate material and a low-K material. Embodiments include a slurry for chemical mechanical polishing a surface comprising cobalt and low-K materials, such as Black Diamond (BD) or SiN, comprising a complexor, an oxidizer, an abrasive, a Co corrosion inhibitor and an ILD suppressor. Embodiments also include a slurry for chemical mechanical polishing a surface comprising a metal and/or silicate material such as cobalt, copper, tantalum, and/or TEOS and a low-K material, such as Black Diamond (BD) or SiN, comprising a complexor, an oxidizer, an abrasive, a corrosion inhibitor, and a non-ionic surfactant.

### CROSS-REFERENCE TO RELATED PATENT APPLICATIONS

This application is a Continuation-In-Part of U.S. application Ser. No. 16/369,193, filed Mar. 29, 2019, incorporated herein by reference in its entirety.

### TECHNICAL FIELD

The present technology generally relates to compositions and methods for polishing surfaces comprising, e.g., cobalt and low-K material. The present technology also relates to compositions and methods for polishing surfaces comprising a metal and/or silicate material and a low-K material.

### BACKGROUND

One of the major chemical mechanical polishing (CMP) challenges for semiconductor manufacturing is the selective polishing of certain materials. Cobalt (Co) has become widely used in semiconductor device fabrication. Similarly, metals such as copper and tantalum, as well as silicate materials such as TEOS, have become widely used in in semiconductor device fabrication. Likewise, low-K materials, such as Black Diamond™ (BD, low-k, SiOC:H) or SiN, are commonly used in interlayer dielectrics (ILD) of semiconductor devices. It has been challenging to use current CMP compositions in Co polishing applications due to high removal rates of ILDs, such as low-K materials.

The art includes US Pub. No. 2017/0158913, in which a non-ionic surfactant, such as Triton™ DF 16 is used in a cobalt polishing composition. However, this composition does not effectively suppress ILD removal rates.

Accordingly, a need exists for novel CMP compositions that can effectively and efficiently remove Co selectively without an increased removal of ILDs. Additionally, a need exists for novel CMP compositions that can effectively and efficiently remove metal and/or silicate materials (e.g., Cu, Ta, and/or TEOS) without an increased removal of ILDs.

### SUMMARY OF THE DISCLOSURE

Provided herein are compositions and methods for polishing surfaces comprising cobalt and optionally a low-K material, e.g., in semiconductor device fabrication. Also provided herein are compositions and methods for polishing surfaces comprising (1) a metal and/or silicate material, such as copper, tantalum, and/or TEOS, and (2) one or more low-K materials, e.g., in semiconductor device fabrication.

### BRIEF DESCRIPTION OF THE DRAWINGS

FIG. 1 shows the molecular weight dependency on the BD removal rate suppression. BD RR suppression was achieved when the chemical (CAS #9038-95-3) with MW 500 was added. As the MW of surfactants (CAS #9038-95-3) increased, BD removal rates were suppressed down to 0 Å/min when this chemical with more than MW 2660. A similar trend was observed from the surfactant (CAS #9003-11-6) at MW 980 as described in FIG. 1. With the chemical (CAS #9003-11-6), lowest BD suppression was observed at 1 Å/min from the one with MW 6000 from CAS #9003-11-6.

FIG. 2 shows the effect of surfactant concentration up to 0.074 wt. %. BD removal rates reached 0 Å/min when 0.074 wt. % of UCON 50-HB-2000 (CAS #9038-95-3) surfactant was added. Slight BD removal rate suppression was observed with more than 0.0029 wt. % of surfactant.

FIG. 3 shows the effect on polishing topography for slurries containing 0.03 wt. % of UCON50-HB surfactants with different molecular weights. The amount of topography correction during the barrier polishing process is substantially greater with the three higher molecular weight versions of the UCON50-HB surfactants.

### DETAILED DESCRIPTION

Provided herein are CMP compositions and methods for polishing surfaces comprising cobalt and optionally a low-K material, e.g., in semiconductor device fabrication. Also provided herein are CMP compositions and methods for polishing surfaces comprising (1) a metal and/or silicate material, such as copper, tantalum, and/or TEOS and (2) one or more low-K materials, e.g., in semiconductor device fabrication.

As used herein, the term “chemical mechanical polishing” or “planarization” refers to a process of planarizing (polishing) a surface with the combination of surface chemical reaction and mechanical abrasion. In some embodiments, the chemical reaction is initiated by applying to the surface a composition (interchangeably referred to as a ‘polishing slurry,’ a ‘polishing composition,’ a ‘slurry composition’ or simply a ‘slurry’) capable of reacting with a surface material, thereby turning the surface material into a product that can be more easily removed by simultaneous mechanical abrasion. In some embodiments, the mechanical abrasion is performed by contacting a polishing pad with the surface, and moving the polishing pad relative to the surface. As used herein, the term “low-K material” is used as it is commonly understood in the art. Low-K material or “low-κ material” is a material with a small relative dielectric constant relative to silicon dioxide. Examples of low-K material include SiN and carbon-doped oxides, such as Black Diamond™ (Applied Materials), Black Diamond™ 2 (Applied Materials), Black Diamond™ 3 (Applied Materials), Aurora™ 2.7 (ASM International N.V.), Aurora™ ULK (ASM International N.V.), etc. As used herein, the terms “metal material,” “silicate material,” or “metal and/or silicate material” is used as it is commonly understood in the art. Examples of metal and/or silicate materials include, but are not limited to, copper (Cu), tantalum (Ta), nickel (Ni), cobalt (Co), and tetraethylorthosilicate (TEOS).

Composition

The CMP polishing compositions disclosed herein can comprise, consist essentially of, or consist of one or more of the following components.

ILD Suppressor

The CMP compositions disclosed herein may comprise one or more ILD suppressors of the following formula (I):

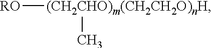

where m is % propylene oxide (PO) by weight, and is 20% to 60% by weight of the total PO and EO units, n is % ethylene oxide (EO) by weight, and is 40% to 80% by weight of the total PO and EO units, R is a C2-7alkyl, and a weight ratio of EO to PO (EO:PO) is 2:3 to 4:1.

In some embodiments, m is about 20%, 25%, 30%, 35%, 40%, 45%, 50%, 55%, or 60% by weight (or ranges thereinbetween) of the total PO and EO units in the ILD suppressor of formula (I). In some embodiments, n is about 40%, 45%, 50%, 55%, 60%, 65%, 70%, 75%, or 80% by weight (or ranges thereinbetween) of the total PO and EO units in the ILD suppressor of formula (I). In some embodiments, the weight ratio of EO to PO (EO:PO) is 2:3, 1:1, 4:3, 5:3, 2:1, 7:3, 8:3, 3:1, 10:3, 11:3, or 4:1, or ranges thereinbetween. In some embodiments, R is a C2, C3, C4, C5, C6, or C7alkyl, which may be branched or linear, and may be optionally substituted.

In some embodiments, the ILD suppressor of formula (I) has a molecular weight of about 1000, 1100, 1200, 1300, 1400, 1500, 1600, 1700, 1800, 1900, 2000, 2100, 2200, 2300, 2400, 2500, 2600, 2700, 2800, 2900, 3000, 3500, 4000, 4500, 5000, 5500, 6000, 6500, or 7000 (or ranges thereinbetween). In some embodiments, the ILD suppressor of formula (I) has a molecular weight of greater than about 1000, 1100, 1200, 1300, 1400, 1500, 1600, 1700, 1800, 1900, 2000, 2100, 2200, 2300, 2400, 2500, 2600, 2700, 2800, 2900, 3000, 3500, 4000, 4500, 5000, 5500, 6000, 6500, or 7000.

In some embodiments, the CMP composition has a concentration of the ILD suppressor of formula (I) of greater than 0.002 wt. %, 0.007 wt. %, or 0.07 wt. %. In some embodiments, the CMP composition has a concentration of the ILD suppressor of formula (I) of about 0.002, 0.003, 0.004, 0.005, 0.006, 0.007, 0.008, 0.009, 0.01, 0.015, 0.02, 0.025, 0.03, 0.035, 0.04, 0.05, 0.06, 0.07, 0.08, 0.09, 0.1 wt. % (or ranges thereinbetween).

Complexor

The CMP compositions of the present disclosure also contain at least one complexor. As used herein, the term “complexor” refers to a chemical compound that interacts with surfaces of metals to be polished during the CMP process. In some embodiments, the complexor is selected from the group consisting of an amino acid having only one acidic moiety, an aminocarboxylic acid, and a phosphonic acid. In some embodiments, the complexor is a nitrogen (N—) containing compound. Particularly, in some embodiments, the complexor comprises or consists of at least one amino group. In some embodiments, the complexor is glycine, α-alanine, β-alanine, N-methylglycine, N,N-dimethylglycine, 2-aminobutyric acid, norvaline, valine, leucine, norleucine, isoleucine, phenylalanine, proline, sarcosine, ornithine, lysine, taurine, serine, threonine, homoserine, tyrosine, bicine, tricine, 3,5-diiodotyrosine, β-(3,4-dihydroxyphenyl)-alanine, thyroxine, 4-hydroxyproline, cysteine, methionine, ethionine, lanthionine, cystathionine, cystine, cysteic acid, aspartic acid, glutamic acid, S-(carboxymethyl)-cysteine, 4-aminobutyric acid, asparagine, azaserine, arginine, canavanine, citrulline, δ-hydroxylysine, creatine, histidine, 1-methylhistidine, 3-methylhistidine, and tryptophan. In some embodiments, the complexor is glycine. These complexors may be used singly, or two or more kinds thereof may be used as mixtures.

In some embodiments, the present CMP composition comprises about 0.1% to about 5% by weight of the complexor. In some embodiments, the present CMP composition comprises about 0.1% to about 5% by weight of the complexor. In some embodiments, the present CMP composition comprises about 0.1% by weight of the complexor. In some embodiments, the present CMP composition comprises about 0.2% by weight of the complexor. In some embodiments, the present CMP composition comprises about 0.3% by weight of the complexor. In some embodiments, the present CMP composition comprises about 0.4% by weight of the complexor. In some embodiments, the present CMP composition comprises about 0.5% by weight of the complexor. In some embodiments, the present CMP composition comprises about 0.6% by weight of the complexor. In some embodiments, the present CMP composition comprises about 0.7% by weight of the complexor. In some embodiments, the present CMP composition comprises about 0.8% by weight of the complexor. In some embodiments, the present CMP composition comprises about 0.9% by weight of the complexor. In some embodiments, the present CMP composition comprises about 1% by weight of the complexor. In some embodiments, the present CMP composition comprises about 2% by weight of the complexor. In some embodiments, the present CMP composition comprises about 3% by weight of the complexor. In some embodiments, the present CMP composition comprises about 4% by weight of the complexor. In some embodiments, the present CMP composition comprises about 5% by weight of the complexor.

Abrasive

The CMP compositions of the present disclosure also contain at least one abrasive. The abrasive in the CMP composition provides or enhances mechanical abrasion effects during the CMP process. Examples of abrasives that can be used in connection with the present disclosure include but are not limited to alumina abrasive, silica abrasive, ceria abrasive, titanium oxide, zirconia, or mixtures thereof. The preferred abrasives are alumina and silica. In order to reduce scratch defects, the mean particle size of the abrasive is preferably controlled. In some embodiments, the particle size profile of the abrasive is measured by D90, which is a characteristic number given by a particle sizing instrument to indicate that the sizes of 90% of particles are less than the characteristic number. In some embodiments, the mean particle size is less than 0.3 micron and the D90 of the abrasive is less than 1 micron. Particularly, in some embodiments, the mean particle size is in between 0.01 and 0.30 micron and D90 is less than 0.5 micron.

In some embodiments, the present CMP composition comprises about 0.01% to about 10% by weight of the abrasive. In some embodiments, the present CMP composition comprises less than 10% by weight of the abrasive. In some embodiments, the present CMP composition comprises less than 9% by weight of the abrasive. In some embodiments, the present CMP composition comprises less than 8% by weight of the abrasive. In some embodiments, the present CMP composition comprises less than 7% by weight of the abrasive. In some embodiments, the present CMP composition comprises less than 6% by weight of the abrasive. In some embodiments, the present CMP composition comprises less than 5% by weight of the abrasive. In some embodiments, the present CMP composition comprises less than 4% by weight of the abrasive. In some embodiments, the present CMP composition comprises less than 3% by weight of the abrasive. In some embodiments, the present CMP composition comprises less than 2% by weight of the abrasive. In some embodiments, the present CMP composition comprises less than 1% by weight of the abrasive. In some embodiments, the present CMP composition comprises less than 0.5% by weight of the abrasive. In some embodiments, the present CMP composition comprises less than 0.2% by weight of the abrasive.

Oxidizer

The CMP compositions of the present disclosure may also contain at least one oxidizer. An oxidizer may be added to the present CMP composition to oxidize a metal surface of a polishing object, thereby enhancing the metal removal rate of the CMP process. In some embodiments, an oxidizer is added to the CMP composition only prior to use. In other embodiments, an oxidizer is mixed with other ingredients of the CMP composition at approximately the same time during a manufacturing procedure. In some embodiments, the present composition is manufactured and sold as a stock composition, and an end customer can choose to dilute the stock composition as needed and/or add a suitable amount of an oxidizer before using.

Examples of the oxidizer which may be used include, but are not limited to, a peroxide, hydrogen peroxide, sodium peroxide, barium peroxide, an organic oxidizer, ozone water, a silver (II) salt, an iron (III) salt, permanganese acid, chromic acid, dichromic acid, peroxodisulfuric acid, peroxophosphoric acid, peroxosulfuric acid, peroxoboric acid, performic acid, peracetic acid, perbenzoic acid, perphthalic acid, hypochlorous acid, hypobromous acid, hypoiodous acid, chloric acid, chlorous acid, perchloric acid, bromic acid, iodic acid, periodic acid, persulfuric acid, dichloroisocyanuric acid, and a salt thereof. The oxidizer may be used either singly or as a mixture of two or more kinds. Among them, hydrogen peroxide, ammonium persulfate, periodic acid, hypochlorous acid, and sodium dichloroisocyanurate are preferable.

Suitable content of the oxidizer can be determined based on particular needs. For example, the metal removal rate may be expected to increase as the concentration of the oxidizer increases. In some embodiments, content of the oxidizer in the CMP composition is 0.1 g/L or more. In some embodiments, content of the oxidizer in the CMP composition is 1 g/L or more. In some embodiments, content of the oxidizer in the CMP composition is 3 g/L or more.

In some embodiments, content of the oxidizer in the CMP composition is greater than 0 and 50 g/L or less. In some embodiments, content of the oxidizer in the CMP composition is greater than 0 and 30 g/L or less. In some embodiments, content of the oxidizer in the CMP composition is greater than 0 and 10 g/L or less. As the content of the oxidizer decreases, the cost involved with materials of the CMP composition can be saved and a load involved with treatment of the CMP composition after polishing use, that is, a load involved with waste treatment, can be reduced. It is also possible to reduce the possibility of excessive oxidation of a surface by reducing the content of an oxidizer.

Corrosion Inhibitors

The CMP compositions of the present disclosure may also contain at least one corrosion inhibitor. The corrosion inhibitor may be any compound that on one hand effectively suppresses corrosion (e.g., of Co, Cu, Ta, Ni, etc.) under the CMP conditions, and on the other hand also permits a high removal rate of a material that is not a low-K material (e.g., a metal and/or silicate material).

In some embodiments, the present CMP composition comprises one or more corrosion inhibitors selected from capryleth-4 carboxylic acid capryleth-6 carboxylic acid, laureth-6-carboxylic acid, oleth-9 carboxylic Acid, oleth-6 carboxylic Acid, oleth-10 carboxylic Acid, lauric acid, potassium laurate, benzotriazole, 5-carboxy benzotriazole, 5-benzimidazole carboxylic acid, 5-Methyl benzotriazol, triethanolamine Laurate, potassium oleate, lauryl ether carboxylic acid, ammonium lauryl sulfate, ammonium laurate, potassium myristate, potassium palmitate, polyoxyethylene alkyl ether phosphate, polyoxyethylene tridecyl ether phosphate, and any lauric acid derivatives. In some embodiments, the present CMP composition the corrosion inhibitor consists of one or more of the above compounds. In some embodiments, the present CMP composition comprises one or more corrosion inhibitors selected from lauric acid and its derivatives. In preferred embodiments, the corrosion inhibitor is potassium laurate. Components, such as those in U.S. Pat. No. 10,059,860, may also be included.

In some embodiments, the present CMP composition comprises about 0.0005% to about 1% by weight of the corrosion inhibitor. In some embodiments, the present CMP composition comprises greater than about 0.0005, 0.0006, 0.0007, 0.0008, 0.0009, 0.001, 0.002, 0.003, 0.004, 0.005, 0.006, 0.007, 0.008, 0.009, 0.01, 0.02, 0.03, 0.04, 0.05, 0.06, 0.07, 0.08, 0.09, 0.10, 0.11, 0.12, 0.13, 0.14, 0.15, 0.16, 0.17, 0.18, 0.19, 0.20, 0.21, 0.22, 0.23, 0.24, 0.25, 0.26, 0.27, 0.28, 0.29, 0.30, 0.35, 0.40, 0.45, 0.50, 0.55, 0.60, 0.65, 0.70, 0.75, 0.80, 0.85, 0.90, 0.95, or 1.0 wt. % of the corrosion inhibitor. In some embodiments, the present CMP composition comprises about 0.0005, 0.0006, 0.0007, 0.0008, 0.0009, 0.001, 0.002, 0.003, 0.004, 0.005, 0.006, 0.007, 0.008, 0.009, 0.01, 0.02, 0.03, 0.04, 0.05, 0.06, 0.07, 0.08, 0.09, 0.10, 0.11, 0.12, 0.13, 0.14, 0.15, 0.16, 0.17, 0.18, 0.19, 0.20, 0.21, 0.22, 0.23, 0.24, 0.25, 0.26, 0.27, 0.28, 0.29, 0.30, 0.35, 0.40, 0.45, 0.50, 0.55, 0.60, 0.65, 0.70, 0.75, 0.80, 0.85, 0.90, 0.95, or 1.0 wt. % of the corrosion inhibitor.

In some embodiments of the present CMP composition, the corrosion inhibitor comprises one or more azole compounds including, but not limited to, benzotriazoles, benzimidazoles, triazoles, imidazole, tolyltriazole, and any combination thereof. Specific examples include, but are not limited to, 1-(1,2-dicarboxyethyl)benzotriazole, 1-[N,N-bis(hydroxyethyl)aminomethyl]benzotriazole, 1-(2,3-dihyroxypropyl)benzotriazole, and 1-(hydroxymethyl)benzotriazole. In some embodiments, the corrosion inhibitor consists of one or more of the above compounds.

Cobalt Corrosion Inhibitors

The CMP compositions of the present disclosure may also contain at least one cobalt corrosion inhibitor. The cobalt corrosion inhibitor may be any compound that on one hand effectively suppresses Co corrosion under the CMP conditions, and on the other hand also permits a high Co removal rate.

In some embodiments, the present CMP composition comprises one or more cobalt corrosion inhibitors selected from capryleth-4 carboxylic acid capryleth-6 carboxylic acid, laureth-6-carboxylic acid, oleth-9 carboxylic Acid, oleth-6 carboxylic Acid, oleth-10 carboxylic Acid, lauric acid, potassium laurate, benzotriazole, 5-carboxy benzotriazole, 5-benzimidazole carboxylic acid, 5-Methyl benzotriazol, triethanolamine Laurate, potassium oleate, lauryl ether carboxylic acid, ammonium lauryl sulfate, ammonium laurate, potassium myristate, potassium palmitate, polyoxyethylene alkyl ether phosphate, polyoxyethylene tridecyl ether phosphate, and any lauric acid derivatives. In some embodiments, the present CMP composition the cobalt corrosion inhibitor consists of one or more of the above compounds. In some embodiments, the present CMP composition comprises one or more cobalt corrosion inhibitors selected from lauric acid and its derivatives. In preferred embodiments, the cobalt corrosion inhibitor is potassium laurate. Components, such as those in U.S. Pat. No. 10,059,860, may also be included.

In some embodiments, the present CMP composition comprises about 0.0005% to about 1% by weight of the cobalt corrosion inhibitor. In some embodiments, the present CMP composition comprises above about 0.01 wt. % of the cobalt corrosion inhibitor. In some embodiments, the present CMP composition comprises above about 0.02 wt. % of the cobalt corrosion inhibitor. In some embodiments, the present CMP composition comprises above about 0.03 wt. % of the cobalt corrosion inhibitor. In some embodiments, the present CMP composition comprises above about 0.04 wt. % of the cobalt corrosion inhibitor. In some embodiments, the present CMP composition comprises above about 0.05 wt. % of the cobalt corrosion inhibitor. In some embodiments, the present CMP composition comprises above about 0.06 wt. % of the cobalt corrosion inhibitor. In some embodiments, the present CMP composition comprises above about 0.07 wt. % of the cobalt corrosion inhibitor. In some embodiments, the present CMP composition comprises above about 0.08 wt. % of the cobalt corrosion inhibitor. In some embodiments, the present CMP composition comprises above about 0.09 wt. % of the cobalt corrosion inhibitor. In some embodiments, the present CMP composition comprises above about 0.1 wt. % of the cobalt corrosion inhibitor. In some embodiments, the present CMP composition comprises above about 0.15 wt. % of the cobalt corrosion inhibitor. In some embodiments, the present CMP composition comprises above about 0.2 wt. % of the cobalt corrosion inhibitor. In some embodiments, the present CMP composition comprises above about 0.25 wt. % of the cobalt corrosion inhibitor. In some embodiments, the present CMP composition comprises above about 0.3 wt. % of the cobalt corrosion inhibitor. In some embodiments, the present CMP composition comprises above about 0.35 wt. % of the cobalt corrosion inhibitor. In some embodiments, the present CMP composition comprises above about 0.4 wt. % of the cobalt corrosion inhibitor. In some embodiments, the present CMP composition comprises above about 0.45 wt. % of the cobalt corrosion inhibitor. In some embodiments, the present CMP composition comprises above about 0.5 wt. % of the cobalt corrosion inhibitor. In some embodiments, the present CMP composition comprises above about 0.6 wt. % of the cobalt corrosion inhibitor. In some embodiments, the present CMP composition comprises above about 0.7 wt. % of the cobalt corrosion inhibitor. In some embodiments, the present CMP composition comprises above about 0.8 wt. % of the cobalt corrosion inhibitor. In some embodiments, the present CMP composition comprises above about 0.9 wt. % of the cobalt corrosion inhibitor. In some embodiments, the present CMP composition comprises above about 1.0 wt. % of the cobalt corrosion inhibitor.

Non-Ionic Surfactant

The CMP compositions disclosed herein may comprise one or more non-ionic surfactants. In some embodiments, the one or more non-ionic surfactants may be selected from the group consisting of polyoxyethylene/polyoxypropylene glycol surfactants and polyalkylene glycol alkyl ethers. In some embodiments, the one or more non-ionic surfactants are polyalkylene glycol monobutylethers, which are block copolymers of ethylene oxide and propylene oxide units. In some embodiments, the non-ionic surfactants have the following formula (I):

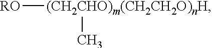

where m is % propylene oxide (PO) by weight, and is 20% to 60% by weight of the total PO and EO units, n is % ethylene oxide (EO) by weight, and is 40% to 80% by weight of the total PO and EO units, R is a C2-7 alkyl, and a weight ratio of EO to PO (EO:PO) is 2:3 to 4:1.

In some embodiments, m is about 20%, 25%, 30%, 35%, 40%, 45%, 50%, 55%, or 60% by weight (or ranges thereinbetween) of the total PO and EO units in the non-ionic surfactant of formula (I). In some embodiments, n is about 40%, 45%, 50%, 55%, 60%, 65%, 70%, 75%, or 80% by weight (or ranges thereinbetween) of the total PO and EO units in the non-ionic surfactant of formula (I). In some embodiments, the weight ratio of EO to PO (EO:PO) is 2:3, 1:1, 4:3, 5:3, 2:1, 7:3, 8:3, 3:1, 10:3, 11:3, or 4:1, or ranges thereinbetween. In some embodiments, R is a C2, C3, C4, C5, C6, or C7alkyl, which may be branched or linear, and may be optionally substituted. In some embodiments, R is a C2-6 alkyl, C2-5 alkyl, C2-4 alkyl, or C2-3 alkyl. In some embodiments, the non-ionic surfactants possess an alcohol group at one end and no other functional groups.

In some embodiments, the non-ionic surfactants are selected from the UCON surfactants In some embodiments, the non-ionic surfactants are UCON50 or UCON75 surfactants, or combinations thereof.

In some embodiments, the one or more non-ionic surfactants of formula (I) has a molecular weight (g/mol) of about 500, 600, 700, 800, 900, 1000, 1100, 1200, 1300, 1400, 1500, 1600, 1700, 1800, 1900, 2000, 2100, 2200, 2300, 2400, 2500, 2600, 2700, 2800, 2900, 3000, 3500, 4000, 4500, 5000, 5500, 6000, 6500, 7000, 7500, 8000, 8500, 9000, 9500, 10000, 10500, 11000, 11500, or 12000 (or ranges thereinbetween). In some embodiments, the one or more non-ionic surfactants of formula (I) has a molecular weight (g/mol) of at least about 500, 600, 700, 800, 900, 1000, 1100, 1200, 1300, 1400, 1500, 1600, 1700, 1800, 1900, 2000, 2100, 2200, 2300, 2400, 2500, 2600, 2700, 2800, 2900, 3000, 3500, 4000, 4500, 5000, 5500, 6000, 6500, 7000, 7500, 8000, 8500, 9000, 9500, 10000, 10500, 11000, 11500, or 12000. In some embodiments, the one or more non-ionic surfactants of formula (I) has a molecular weight (g/mol) of no greater than about 12000, 11500, 11000, 10500, 10000, 9500, 9000, 8500, 8000, 7500, 7000, 6500, 6000, 5500, 5000, 4500, 4000, 3500, 3000, 2900, 2800, 2700, 2600, 2500, 2400, 2300, 2200, 2100, 2000, 1900, 1800, 1700, 1600, 1500, 1400, 1300, 1200, 1100, 1000, 900, 800, 700, 600, or 500.

In some embodiments, the CMP composition has a concentration (wt. %) of the non-ionic surfactant of formula (I) of greater than about 0.010, 0.015, 0.020, 0.025, 0.030, 0.035, 0.040, 0.045, 0.050, 0.055, 0.060, 0.065, 0.070, 0.075, 0.080, 0.085, 0.090, 0.095, 0.10, 0.11, 0.15, 0.20, 0.25, 0.30, 0.35, 0.40, 0.45, or 0.50 wt. %. In some embodiments, the CMP composition has a concentration of the one or more ionic surfactants of formula (I) of about 0.010, 0.015, 0.020, 0.025, 0.030, 0.035, 0.040, 0.045, 0.050, 0.055, 0.060, 0.065, 0.070, 0.075, 0.080, 0.085, 0.090, 0.095, 0.10, 0.11, 0.15, 0.20, 0.25, 0.30, 0.35, 0.40, 0.45, or 0.50 wt. % (or ranges thereinbetween).

pH Adjusting Agent

In some embodiments, the present CMP composition further comprises at least one pH adjusting agent. In some embodiments, the pH of the present CMP composition is, although not particularly limited, in the range of about 1 to about 13, inclusive of the end points. In some embodiments, the pH of the present CMP composition is in the range of about 1.5 to about 12.5, inclusive of the end points. In some embodiments, the pH of the present CMP composition is in the range of about 2 to about 12, inclusive of the end points. In some embodiments, the pH of the present CMP composition is in the range of about 2.5 to about 11.5, inclusive of the end points. In some embodiments, the pH of the present CMP composition is in the range of about 3 to about 11, inclusive of the end points. In some embodiments, the pH of the present CMP composition is in the range of about 3.5 to about 10.5, inclusive of the end points. In some embodiments, the pH of the present CMP composition is in the range of about 4 to about 10, inclusive of the end points. In some embodiments, the pH of the present CMP composition is in the range of about 4.5 to about 9.5, inclusive of the end points. In some embodiments, the pH of the present CMP composition is in the range of about 5 to about 9, inclusive of the end points. In some embodiments, the pH of the present CMP composition is in the range of about 6 to about 9, inclusive of the end points. In some embodiments, the pH of the present CMP composition is in the range of about 5.5 to about 8.5, inclusive of the end points. In some embodiments, the pH of the present CMP composition is in the range of about 6 to about 8, inclusive of the end points. In some embodiments, the pH of the present CMP composition is about 7. In some embodiments, the pH of the present CMP composition is about 7.5.

In some embodiments, the pH of the present CMP composition is in the range of about 6 to about 9, inclusive of the end points. In some embodiments, the pH of the present CMP composition is in the range of about 6 to about 10, inclusive of the end points. In some embodiments, the pH of the present CMP composition is in the range of about 6 to about 11, inclusive of the end points. In some embodiments, the pH of the present CMP composition is in the range of about 6 to about 12, inclusive of the end points.

In some embodiments of the CMP composition, the pH is between about 9 and about 11, inclusive of the end points. In some embodiments of the CMP composition, the pH is about 9.0, 9.1, 9.2, 9.3, 9.4, 9.5, 9.6, 9.7, 9.8, 9.9, 10.0, 10.1, 10.2, 10.3, 10.4, 10.5, 10.6, 10.7, 10.8, 10.9, or 11.0 (or ranges thereinbetween).

In some embodiments, an acid or an alkali is used as the pH adjusting agent. The acid or alkali used in connection with the present invention can be organic or inorganic compounds. Examples of the acid include inorganic acids such as sulfuric acid, nitric acid, boric acid, carbonic acid, hypophosphorous acid, phosphorous acid, and phosphoric acid; and organic acids such as carboxylic acids including formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, and lactic acid, and organic sulfuric acids including methanesulfonic acid, ethanesulfonic acid, and isethionic acid. Examples of the alkali include hydroxides of an alkali metal, such as potassium hydroxide; ammonium hydroxide, ethylene diamine, and piperazine; and quaternary ammonium salts such as tetramethyl ammonium hydroxide and tetraethyl ammonium hydroxide. These acids or alkalis can be used either singly or in combination of two or more types.

Content of the acid or alkali in the CMP composition is not particularly limited as long as it is an amount allowing the CMP composition to be within the aforementioned pH range.

Other Components

The CMP composition of the present invention may contain, if necessary, other components, such as a preservative, a biocide, a reducing agent, a polymer, a surfactant, or the like.

In some embodiments, for the purpose of enhancing the hydrophilicity of the surface to be polished or increasing the dispersion stability of abrasive, a water soluble polymer may be added to the present CMP composition. Examples of the water soluble polymer include a cellulose derivative such as hydroxymethyl cellulose, hydroxyethyl cellulose (HEC), hydroxypropyl cellulose, hydroxyethylmethyl cellulose, hydroxypropylmethyl cellulose, methyl cellulose, ethyl cellulose, ethylhydroxyethyl cellulose, or carboxymethyl cellulose; an imine derivative such as poly(N-acylalkyleneimine); polyvinyl alcohol; modified (cation modified or non-ion modified) polyvinyl alcohol; polyvinyl pyrrolidone; polyvinylcaprolactam; polyoxyalkylene such as polyoxyethylene; and a copolymer containing those constitutional units. The water-soluble polymer may comprise pullalan. The water soluble polymer may be used either alone or as a mixture of two or more kinds.

In some embodiments, the CMP composition according to the present disclosure may also comprise a biocide or other preservatives. Examples of preservatives and biocides that may be used in connection with the present invention include an isothiazoline-based preservative such as 2-methyl-4-isothiazolin-3-one or 5-chloro-2-methyl-4-isothiazolin-3-one, paraoxybenzoate esters, and phenoxyethanol, and the like. These preservatives and biocides may be used either alone or in mixture of two or more kinds thereof.

Methods and Compositions

In another aspect of the present disclosure, provided herein are methods for chemical mechanical polishing (CMP) of an object having at least one surface. The method comprises contacting the surface with a polishing pad; delivering a CMP composition according to the present disclosure to the surface; and polishing said surface with the CMP composition. In some embodiments, the surface includes cobalt and optionally one or more low-K material.

In another aspect of the present disclosure, provided herein are methods for chemical mechanical polishing (CMP) of an object having at least one surface. The method comprises contacting the surface with a polishing pad; delivering a CMP composition according to the present disclosure to the surface; and polishing said surface with the CMP composition. In some embodiments, the surface includes one or more metal and/or silicate materials (e.g, Cu, Ta, and/or TEOS) and one or more low-K materials. In an embodiment, the compositions of the present disclosure polish an object having a layer comprising tantalum, copper, and/or TEOS and a low-K material.

In another aspect of the present disclosure, provided herein are methods for selectively removing cobalt in the presence of one or more low-K material during a chemical mechanical polishing (CMP) process. The method comprises using the CMP composition according to the present disclosure.

In another aspect of the present disclosure, provided herein are methods for selectively removing one or more metal and/or silicate materials (e.g., Cu, Ta, and/or TEOS) in the presence of one or more low-K materials during a chemical mechanical polishing (CMP) process. The method comprises using the CMP composition according to the present disclosure.

In another aspect of the present disclosure, provided herein are systems for chemical mechanical polishing (CMP). The system comprises a substrate comprising at least one surface having cobalt and optionally one or more low-K material, a polishing pad, and a CMP composition according to the present disclosure.

In another aspect of the present disclosure, provided herein are systems for chemical mechanical polishing (CMP). The system comprises a substrate comprising at least one surface comprising one or more metal and/or silicate materials (e.g., Cu, Ta, and/or TEOS) and one or more low-K materials, a polishing pad, and a CMP composition according to the present disclosure.

In yet another aspect of the present disclosure, provided herein is a substrate comprising at least one surface cobalt and optionally one or more low-K material, wherein the substrate is in contact with a chemical mechanical polishing (CMP) composition according to the present disclosure.

In yet another aspect of the present disclosure, provided herein is a substrate comprising at least one surface comprising one or more metal and/or silicate materials (e.g., Cu, Ta, and/or TEOS) and one or more low-K materials, wherein the substrate is in contact with a chemical mechanical polishing (CMP) composition according to the present disclosure.

In some embodiments, the present methods and compositions are suitable for polishing a Co surface. An apparatus or conditions commonly used for Co polishing can be adopted and modified according to particular needs. The selections of a suitable apparatus and/or conditions for carrying out the present methods are within the knowledge of a skilled artisan.

In some embodiments, the present methods result in a cobalt removal rate of greater than 500 Å/min, e.g., about 500, 600, 700, 800, 900, 1000, 1100, 1200, 1300, 1400, 1500, 1600, 1700, 1800, 1900, 2000, 2100, 2200, 2300, 2400, 2500, 2600, 2700, 2800, 2900, 3000, 3100, 3200, 3300, 3400, 3500, 3600, 3700, 3800, 3900, or 4000 Å/min. In some embodiments, the present methods result in a low-K material removal rate of less than 15 Å/min, e.g., less than about 15, 14, 13, 12, 11, 10, 9, 8, 7, 6, 5, 4, 3, 2, 1, 0.1, or 0 Å/min. In some embodiments, the present methods result in a selectivity (cobalt removal rate to low-K material removal rate) of greater than 500, e.g., greater than 600, 700, 800, 900, 1000, 1100, 1200, 1300, 1400, 1500, 1600, 1700, 1800, 1900, 2000, 2100, 2200, 2300, 2400, 2500, 2600, 2700, 2800, 2900, 3000, 3100, 3200, 3300, 3400, 3500, 3600, 3700, 3800, 3900, or 4000.

In some embodiments, the present methods and compositions are suitable for polishing a surface comprising a metal and/or silicate material (e.g, Cu, Ta, and/or TEOS) and one or more low-K materials. An apparatus or conditions commonly used for metal, silicate, and/or low-K material polishing can be adopted and modified according to particular needs. The selections of a suitable apparatus and/or conditions for carrying out the present methods are within the knowledge of a skilled artisan.

In some embodiments, the present methods result in a copper, tantalum, and/or TEOS removal rate of greater than 70 Å/min, e.g., about 70, 75, 80, 85, 90, 95, 100, 200, 300, 400, 500, 600, 700, 800, 900, 1000, 1100, 1200, 1300, 1400, 1500, 1600, 1700, 1800, 1900, 2000, 2100, 2200, 2300, 2400, 2500, 2600, 2700, 2800, 2900, 3000, 3100, 3200, 3300, 3400, 3500, 3600, 3700, 3800, 3900, or 4000 Å/min. In some embodiments, the present methods result in a low-K material removal rate of less than 200 Å/min, e.g., less than about 200, 190, 180, 170, 160, 150, 140, 130, 120, 110, 100, 90, 80, 70, 65, 60, 55, 50, 45, 40, 35, 30, 25, 20, 15, 14, 13, 12, 11, 10, 9, 8, 7, 6, 5, 4, 3, 2, 1, 0.1, or 0 Å/min. In some embodiments, the present methods result in a selectivity (metal and/or silicate removal rate to low-K material removal rate) of greater than 10, e.g., greater than 10, 20, 30, 40, 50, 60, 70, 80, 90, 100, 200, 300, 400, 500 600, 700, 800, 900, 1000, 1100, 1200, 1300, 1400, 1500, 1600, 1700, 1800, 1900, 2000, 2100, 2200, 2300, 2400, 2500, 2600, 2700, 2800, 2900, 3000, 3100, 3200, 3300, 3400, 3500, 3600, 3700, 3800, 3900, or 4000. In an embodiment, the copper, tantalum, and/or TEOS removal rate is greater than 200 Å/min and, the low-K material removal rate is less than 70 Å/min.

In some embodiments, the surface comprises tantalum, and the present methods result in a tantalum removal rate of greater than 200 Å/min, e.g., about 200, 300, 400, 500, 600, 700, 800, 900, 1000, 1100, 1200, 1300, 1400, 1500, 1600, 1700, 1800, 1900, 2000, 2100, 2200, 2300, 2400, 2500, 2600, 2700, 2800, 2900, 3000, 3100, 3200, 3300, 3400, 3500, 3600, 3700, 3800, 3900, or 4000 Å/min. In an embodiment, the tantalum removal rate is greater than 400 Å/min.

In some embodiments, the surface comprises copper, and the present methods result in a copper removal rate of greater than 70 Å/min, e.g., about 70, 75, 80, 85, 90, 95, 100, 200, 300, 400, 500, 600, 700, 800, 900, 1000, 1100, 1200, 1300, 1400, 1500, 1600, 1700, 1800, 1900, 2000, 2100, 2200, 2300, 2400, 2500, 2600, 2700, 2800, 2900, 3000, 3100, 3200, 3300, 3400, 3500, 3600, 3700, 3800, 3900, or 4000 Å/min. In an embodiment, the copper removal rate is greater than 200 Å/min.

In some embodiments, the surface comprises TEOS, and the present methods result in a TEOS removal rate of greater than 70 Å/min, e.g., about 70, 75, 80, 85, 90, 95, 100, 200, 300, 400, 500, 600, 700, 800, 900, 1000, 1100, 1200, 1300, 1400, 1500, 1600, 1700, 1800, 1900, 2000, 2100, 2200, 2300, 2400, 2500, 2600, 2700, 2800, 2900, 3000, 3100, 3200, 3300, 3400, 3500, 3600, 3700, 3800, 3900, or 4000 Å/min. In an embodiment, the TEOS removal rate is greater than 200 Å/min.

It is noted that, as used herein and in the appended claims, the singular forms “a”, “an”, and “the” include plural referents unless the context clearly dictates otherwise. It is further noted that the claims may be drafted to exclude any optional element. As such, this statement is intended to serve as antecedent basis for use of such exclusive terminology as “solely”, “only” and the like in connection with the recitation of claim elements, or use of a “negative” limitation.

The term “about” will be understood by persons of ordinary skill in the art and will vary to some extent depending upon the context in which it is used. If there are uses of the term which are not clear to persons of ordinary skill in the art given the context in which it is used, “about” will mean up to plus or minus 10% of the particular term. Certain ranges are presented herein with numerical values being preceded by the term “about”. The term “about” is used herein to provide literal support for the exact number that it precedes, as well as a number that is near to or approximately the number that the term precedes. In determining whether a number is near to or approximately a specifically recited number, the near or approximating unrecited number may be a number, which, in the context in which it is presented, provides the substantial equivalent of the specifically recited number.

Where a range of values is provided, it is understood that each intervening value, to the tenth of the unit of the lower limit unless the context clearly dictates otherwise, between the upper and lower limit of that range and any other stated or intervening value in that stated range, is encompassed within the invention. The upper and lower limits of these smaller ranges may independently be included in the smaller ranges and are also encompassed within the invention, subject to any specifically excluded limit in the stated range. Where the stated range includes one or both of the limits, ranges excluding either or both of those included limits are also included in the invention.

This disclosure is not limited to particular embodiments described, as such may, of course, vary. It is also to be understood that the terminology used herein is for the purpose of describing particular embodiments only, and is not intended to be limiting, since the scope of the present invention will be limited only by the appended claims.

As will be apparent to those of skill in the art upon reading this disclosure, each of the individual embodiments described and illustrated herein has discrete components and features which may be readily separated from or combined with the features of any of the other several embodiments without departing from the scope or spirit of the present invention. Any recited method can be carried out in the order of events recited or in any other order that is logically possible.

All publications and patents cited in this specification are herein incorporated by reference as if each individual publication or patent were specifically and individually indicated to be incorporated by reference and are incorporated herein by reference to disclose and describe the methods and/or materials in connection with which the publications are cited. The citation of any publication is for its disclosure prior to the filing date and should not be construed as an admission that the present invention is not entitled to antedate such publication by virtue of prior invention. Further, the dates of publication provided may be different from the actual publication dates that may need to be independently confirmed.

The following examples are given for the purpose of illustrating various embodiments of the disclosure and are not meant to limit the present disclosure in any fashion. One skilled in the art will appreciate readily that the present disclosure is well adapted to carry out the objects and obtain the ends and advantages mentioned, as well as those objects, ends and advantages inherent herein. The present examples, along with the methods described herein are presently representative of embodiments and are exemplary, and are not intended as limitations on the scope of the disclosure. Changes therein and other uses which are encompassed within the spirit of the disclosure as defined by the scope of the claims will occur to those skilled in the art.

### EXAMPLES

TABLE 1
UCON surfactants used in this study

| | | | | | | Carbon | | |
|---|---|---|---|---|---|---|---|---|
| | | | | | EO/PO | # on | # of | # of |
| | | CAS | Ethylene | Propylene | ratio by | alkyl | EO | PO |
| Name | MW | number | oxide | oxide | weight | group | units | units |
| UCON 50-HB-100 | 520 | 9038-95-3 | 50% | 50% | 1 | 4 | 5 | 4 |
| UCON 50-HB-260 | 970 | 9038-95-3 | 50% | 50% | 1 | 4 | 10 | 8 |
| UCON 50-HB-400 | 1230 | 9038-95-3 | 50% | 50% | 1 | 4 | 13 | 10 |
| UCON 50-HB-660 | 1590 | 9038-95-3 | 50% | 50% | 1 | 4 | 17 | 13 |
| UCON 50-HB-2000 | 2660 | 9038-95-3 | 50% | 50% | 1 | 4 | 30 | 22 |
| UCON 50-HB-3520 | 3380 | 9038-95-3 | 50% | 50% | 1 | 4 | 38 | 29 |
| UCON 50-HB-5100 | 3930 | 9038-95-3 | 50% | 50% | 1 | 4 | 44 | 33 |
| UCON 75-H-450 | 980 | 9003-11-6 | 75% | 25% | 3 | 4 | 16 | 4 |
| UCON 75-H-1400 | 2500 | 9003-11-6 | 75% | 25% | 3 | 4 | 42 | 11 |
| UCON 75-H-9500 | 6000 | 9003-11-6 | 75% | 25% | 3 | 4 | 101 | 26 |
| UCON 75-H-90000 | 12000 | 9003-11-6 | 75% | 25% | 3 | 4 | 204 | 51 |

Typical CMP composition formulations are described in Table 2. Slurry A is the base formulation. As described in slurry R, x % of ILD suppressor was added into base formulation A. That formulation became slurry XX.

TABLE 2
Typical formulations at POU formulation (the rest is DIW)

| Slurry name | Slurry A | Slurry R | Slurry Y | Slurry Z |
|---|---|---|---|---|
| Silica content | 0.43% | 0.43% | 0.43% | 0.43% |
| KOH | 0.013% | 0.013% | 0.013% | 0.013% |
| Glycine | 1.13% | 1.13% | 1.13% | 1.13% |
| Potassium laurate | 0.0013% | 0.0013% | 0.0013% | 0.0013% |
| Kordek MLX | 0.00038% | 0.00038% | 0.00038% | 0.00038% |
| (Methylisothiazolone) | | | | |
| Ucon 50-HB-2000 | — | 0.074% | 0.00074% | 0.0074% |

Polishing Conditions

Benchtop Polisher
Polisher: Allied TechPrep Benchtop polisher (1.5-inch×1.5-inch coupon)
Pad: VP6000 pad
Flow rate: 90 mL/min
Platen speed: 250 rpm
Polishing time: 3 min for BD, 30 secs for Co
Down force: 1 psi
Dilution factor: 3.3×
H₂O₂ (POU): 0.68 wt. %

Westech Polisher
Polisher: Westech 372M polisher (200 mm wafer)
Pad: VP6000 pad
Flow rate: 200 mL/min
Platen speed: 93/87 rpm
Polishing time: 1 min for BD and SiN, 15 secs for Co
Down force: 1.5 psi
Dilution factor: 3.3×
H₂O₂ (POU): 0.68 wt. %

Reflexion LK Polisher
Polisher: Reflexion LK (300 mm wafer)
Pad: VP6000 pad
Flow rate: 200 mL/min
Platen speed: 90 rpm
Polishing time: 1 min for BD and SiN, 10 secs for Co
Down force: 1.5 psi
Dilution factor: 3.3×
H₂O₂ (POU): 0.68 wt. %

Initial screening results with various surfactants described in Table 3. It shows that the formulation containing UCON-50-HB-2000 produced complete BD suppression with high PVD Co removal rate. Specifically, Slurry N contains Triton DF-16 surfactant, which was claimed a good BD suppressor in prior art, US2017/0158913 A1. BD removal rate from this surfactant was 3 Å/min in slurry N. However, the Co removal rate was quite low, compared to the formulation with chemical 9038-95-3 probably due to more hydrophobic tail group from Triton DF-16 containing 8 to 10 carbon atoms.

TABLE 3
Surfactant Screening results; Data collected from Westech polisher. Slurry I
(CAS# 9038-95-3) only produced high Co RR and 0 Å/min BD RR.

| | | Surfactant | | | | |
|---|---|---|---|---|---|---|
| Slurry | | concentration | Co RR | BD RR | | |
| name | CAS # | at POU (%) | (Å/min) | (Å/min) | Surfactant | Chemical name |
| Slurry A | 10124-65-9 | — | 7508 | 30 | Potassium | Potassium laurate |
| | | | | | laurate | |
| Slurry B | 68412-59-9 | 0.074% | 0 | 0 | ETHFAC 102 | Mixed lauryl and |
| | | | | | | myristyl phosphate |
| Slurry C | 73038-25-2 | 0.074% | 0 | 0 | ETHFAC 193 | Polyoxyethylene |
| | | | | | | tridecyl ether phosphate |
| Slurry D | 220622-96-8 | 0.074% | 43 | 0 | Akypo RLM25 | Laureth-4 |
| | | | | | | carboxylic acid |
| Slurry F | 57635-48-0 | 0.074% | 67 | 6 | Akypo RO | Oleth-3 |
| | | | | | 20VG | Carboxylic Acid |
| Slurry G | 68081-96-9 | 0.074% | 1829 | 14 | Ammonium | Ammonium lauryl sulfate |
| | | | | | lauryl sulfate | |
| Slurry H | 57-09-0 | 0.074% | 181 | 9 | CTAB | Cetrimonium bromide |
| | | | | | (Cetrimonium | |
| | | | | | bromide) | |
| Slurry I | 9038-95-3 | 0.074% | 7580 | 0 | Ucon 50-HB- | Polyalkylene glycol |
| | | | | | 2000 | monobutyl ether |
| Slurry J | 9005-00-9 | 0.074% | 327 | 0 | Brij S100 | Polyoxyethylene |
| | | | | | | (100) Stearyl Ether |
| Slurry K | 9014-93-1 | 0.074% | 367 | 0 | Ethal DNP-18 | Polyoxyethylene |
| | | | | | | dinonyl phenyl ether |
| Slurry L | 9003-11-6 | 0.074% | 71 | 2 | PLONON201 | Oxirane, methyl-, |
| | | | | | | polymerwith oxirane |
| Slurry M | 9003-39-8 | 0.074% | 7986 | 8 | PVP K15 | Polyvinyl pyrrolidine |
| Slurry N | 68603-25-8 | 0.074% | 146 | 3 | Trition DF-16 | Alcohols, C8-C10, |
| | | | | | | ethoxylated propoxylated |

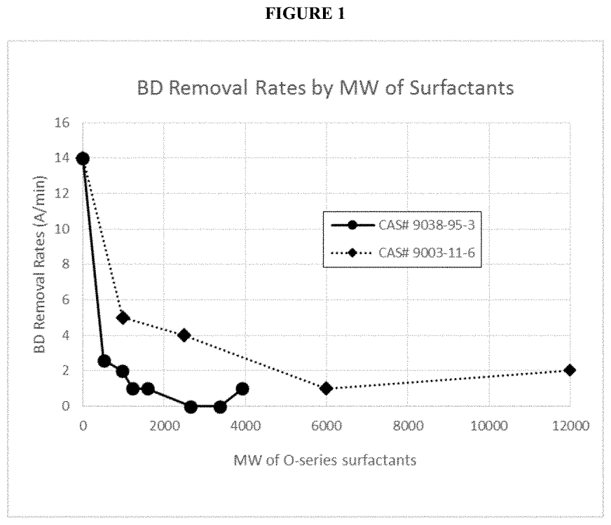

FIG. 1 shows the molecular weight dependency on the BD removal rate suppression. BD RR suppression was achieved when the chemical (CAS #9038-95-3) with MW 500 was added. As the MW of surfactants (CAS #9038-95-3) increased, BD removal rates were suppressed down to 0 Å/min when this chemical with more than MW 2660. A similar trend was observed from the surfactant (CAS #9003-11-6) at MW 980 as described in FIG. 1. With the chemical (CAS #9003-11-6), lowest BD suppression was observed at 1 Å/min from the one with MW 6000 from CAS #9003-11-6.

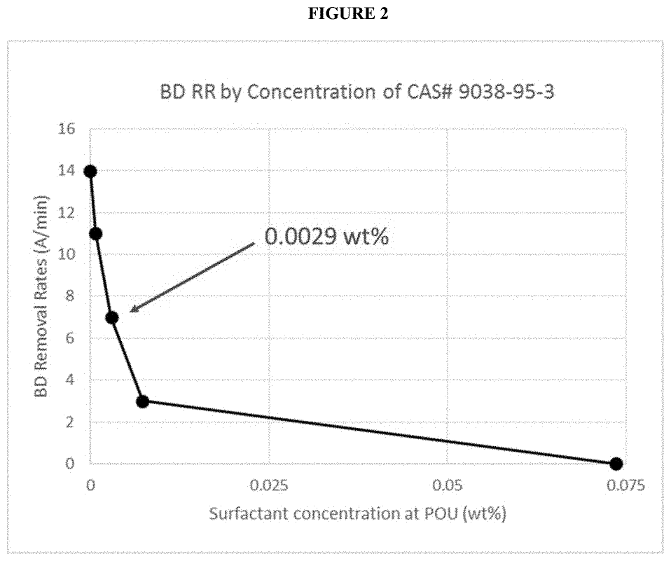

FIG. 2 shows the effect of surfactant concentration up to 0.074 wt. %. BD removal rates reached 0 Å/min when 0.074 wt. % of UCON 50-HB-2000 (CAS #9038-95-3) surfactant was added. Slight BD removal rate suppression was observed with more than 0.0029 wt. % of surfactant.

These results showed that surfactants with CAS #9038-95-3 or CAS #9003-11-6 produced further BD removal rates suppression as molecular weight increase and BD suppression could be achieved when more than 0.0029 wt. % surfactant was added into slurry formulations. Table 3 summarized the all the slurry used in this study.

From the data in FIG. 1, BD RR suppression is affected by the ratio of EO/PO repeating units. When the molecule around MW 1000 in Table 4, BD RR from Slurry R (MW 2660) was 0 Å/min while that from Slurry V (MW 2500) was 4 Å/min. This result indicates that the ratio between EO/PO (by weight) plays an important role in the suppression of BD RR. Lower the EO/PO ratio, higher the BD suppression. It also shows the range of EO/PO ratio between 1 and 3 is suitable for efficient BD RR suppression to increase selectivity. So far, authors have tested these two chemicals with various MWs. Possibly, chemicals with EO/PO ratio less than 1 may produce good BD suppression as well as high Co/BD selectivity than these chemicals.

Furthermore, slurries with chemicals >MW 3930 from CAS #9038-95-3 and >12000 from CAS #9003-11-6 started producing reduced Co RR, which indicates that too big molecule with high MW are not suitable to be used for high Co RR and stop-on BD application.

TABLE 4
Surfactant concentrations and MW in slurries tested in this IDF. EO/PO ratio
by weight shows the difference of two chemicals used in this study. Selectivity
data show the MWs effective on BD suppression for each chemical.

| | | | EO/PO | Surfactant | | | |
|---|---|---|---|---|---|---|---|
| Slurry | | | ratio by | concentration | Co RR | BD RR | Selectivity |
| name | MW | CAS # | weight | at POU (%) | (Å/min) | (Å/min) | (Co/BD) |
| Slurry A | — | — | — | — | 3278 | 14 | 234 |
| Slurry N | 520 | 9038-95-3 | 1 | 0.074% | 2172 | 3 | 835 |
| Slurry O | 970 | 9038-95-3 | 1 | 0.074% | 1973 | 2 | 987 |
| Slurry P | 1230 | 9038-95-3 | 1 | 0.074% | 1884 | 1 | 1884 |
| Slurry Q | 1590 | 9038-95-3 | 1 | 0.074% | 2105 | 1 | 2105 |
| Slurry R | 2660 | 9038-95-3 | 1 | 0.074% | 1864 | 0 | >2000 |
| Slurry S | 3380 | 9038-95-3 | 1 | 0.074% | 2163 | 0 | >2000 |
| Slurry T | 3930 | 9038-95-3 | 1 | 0.074% | 1691 | 1 | 1691 |
| Slurry U | 980 | 9003-11-6 | 3 | 0.074% | 1726 | 5 | 345 |
| Slurry V | 2500 | 9003-11-6 | 3 | 0.074% | 1768 | 4 | 442 |
| Slurry W | 6000 | 9003-11-6 | 3 | 0.074% | 1926 | 1 | 1926 |
| Slurry X | 12000 | 9003-11-6 | 3 | 0.074% | 474 | 2 | 237 |
| Slurry Y | 2660 | 9038-95-3 | 1 | 0.00074% | 3027 | 11 | 275 |
| Slurry Z | 2660 | 9038-95-3 | 1 | 0.00290% | 2100 | 7 | 300 |
| Slurry AA | 2660 | 9038-95-3 | 1 | 0.0074% | 2982 | 3 | 994 |

Table 5 shows the removal rates from 300 mm polisher with slurry Z containing 0.0029% of CAS #9038-95-3. Actually selectivity (1923), was much higher due to high Co RR (3387 Å/min) and low BD RR (2 Å/min) compared to the data obtained from benchtop polisher (Co RR: 2100 Å/min, BD RR: 7 Å/min). It indicates that actual BD RR could be possibly further suppressed when the slurry containing the chemical is used in big polishers. So even slurry Y contains 0.00074 wt. % of the chemical in POU formulation, it could be expected that much lower BD rates could be expected even BD.

TABLE 5
Removal rate from 300 mm polisher.

| | | | EO/PO | Surfactant | | | |
|---|---|---|---|---|---|---|---|
| Slurry | | | ratio by | concentration | Co RR | BD RR | Selectivity |
| name | MW | CAS # | weight | at POU (%) | (Å/min) | (Å/min) | (Co/BD) |
| Slurry A | — | — | — | — | 3880 | 12 | 324 |
| Slurry Z | 2660 | 9038-95-3 | 1 | 0.00290% | 3387 | 2 | 1923 |

Table 6 shows the composition for a different set of CMP slurries. The table shows that the slurry composition includes 0.03 wt. % of a UCON50-HB surfactant, the molecular weight of which may be varied.

TABLE 6
Composition for CMP slurries containing 0.03 wt. %
UCON50-HB surfactants.

| Component | | | |
|---|---|---|---|
| (Product Name) | Chemical Name | wt-% | Ratio [−] |
| PL-3L colloidal silica | Colloidal silica SiO₂ | 41.03 | 0.4103 |
| Potassium hydroxide | Potassium hydroxide KOH | 2.34 | 0.0234 |
| Citric Acid | Citric acid | 0.68 | 0.0068 |
| Benzotriazole | 1,2,3-benzotriazole | 0.13 | 0.0013 |
| Pullulan | (C₁₈H₃₀O₁₅)ₙ | 0.08 | 0.0008 |
| Newkalgen FS-3AQ | Organic phosphate anionics | 0.16 | 0.0016 |
| UCON75H-1400 | Polyalkylene Glycol | 0.06 | 0.0006 |
| | Monobutyl Ether | | |
| UCON50-HB-xxxx | Polyalkylene Glycol | 0.03 | 0.0003 |
| | Monobutyl Ether | | |
| H₂O | | 55.5 | 0.555 |
| Total | | 100.0 | 1.000 |

Table 7 shows the effect of increasing surfactant molecular weight on removal rates with two dielectric substrate wafers, when the amount of surfactant is low (0.03 wt. %). When the molecular weight exceeds 2000 g/mole, the BD removal rate is approximately one-third the removal rate observed for the lower molecular weight surfactants. The BD or Black Diamond material has a lower K value, so it has greater resistance to electrical current passing through and is preferred for the smaller, newer-generation chips. The removal rate of the older generation TEOS substrate is not significantly impacted by the molecular weight increase, but the new BD material shows a significant reduction in the polishing rate with increasing molecular weight.

TABLE 7
Effect of non-ionic surfactant molecular weight
on Ta, Cu, TEOS, and BD removal rates.

| | Surfactant | | Removal Rate (Å/min) | | | |
|---|---|---|---|---|---|---|
| Slurry ID # | Name | MW | Ta | Cu | TEOS | BD |
| FCB965-1708 | UCON50-HB-260 | 970 | 511 | 260 | 271 | 154 |
| FCB965-1707 | UCON50-HB-400 | 1230 | 562 | 280 | 289 | 128 |
| FCB965-1709 | UCON50-HB-660 | 1590 | 498 | 250 | 281 | 109 |
| FCB965-1637 | UCON50-HB- | 2660 | 470 | 200 | 243 | 68 |
| | 2000 | | | | | |
| FCB965-1711 | UCON50-HB- | 3400 | 546 | 250 | 251 | 52 |
| | 3520 | | | | | |
| FCB965-1712 | UCON50-HB- | 3900 | 512 | 270 | 273 | 43 |
| | 5100 | | | | | |

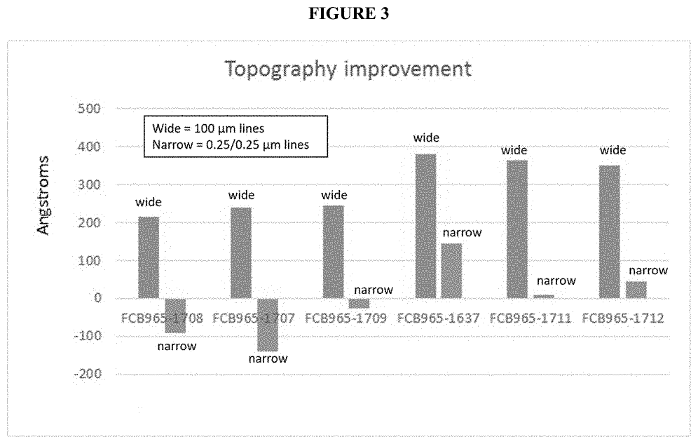

FIG. 3 shows the effect on polishing topography for the same set of slurries. The amount of topography correction during the barrier polishing process is substantially greater with the three higher molecular weight UCON50-HB surfactants.

Table 8 shows composition data for a different set of CMP slurries, where the amount of surfactant is one order of magnitude higher than for the composition shown in Table 6. The table shows that the CMP compositions thus prepared include 0.32 wt. % of a UCON surfactant, for which the molecular weight and polyoxyethylene/polyoxypropylene ratio may be varied.

TABLE 8
Slurry composition including 0.32 wt. % UCON surfactants.

| Component | | | |
|---|---|---|---|
| (Product Name) | Chemical Name | wt-% | Ratio [−] |
| SS-FA colloidal silica | Colloidal silica SiO₂ | 40.9 | 0.409 |
| Potassium hydroxide | Potassium hydroxide KOH | 2.34 | 0.0234 |
| Citric Acid | Citric acid | 0.68 | 0.0068 |
| Benzotriazole | 1,2,3-benzotriazole | 0.19 | 0.0019 |
| Pullulan | (C₁₈H₃₀O₁₅)ₙ | 0.08 | 0.0008 |
| Newkalgen FS-3AQ | Organic phosphate anionics | 0.16 | 0.0016 |
| UCONxxx | Polyalkylene Glycol | 0.32 | 0.0032 |
| | Monobutyl Ether | | |
| H₂O | | 55.3 | 0.553 |
| Total | | 100.0 | 1.000 |

Table 9 shows the results of this study, where the amount of surfactant is one order of magnitude higher than in the compositions tested in Table 7. In this case, the black diamond removal rate is affected, even with the lower molecular weight surfactants, although the smaller surfactants are still not as effective in reducing the removal rate as the larger surfactants. Testing with the UCON75-H type of surfactants shows a similar trend, although this group of surfactants requires a higher molecular weight to be as effective as the HB-50 UCON materials. The difference between these two types of surfactants lies in the ratio of polyoxyethylene units to polyoxypropylene units in the surfactant chain. The UCON50-HB surfactants have equal amounts of the two types of units while the UCON75-H surfactants have 75% polyoxyethylene units and 25% polyoxypropylene units.

TABLE 9
Effect of surfactant molecular weight and polyoxyethylene/
polyoxypropylene ratio on removal rates.

| Surfactant | | Removal Rate (Å/min) | | | |
|---|---|---|---|---|---|
| UCON Name | MW | Ta | Cu | TEOS | BD |
| 50-HB-100 | 520 | 201 | 97 | 123 | 95 |
| 50-HB-260 | 970 | 291 | 75 | 113 | 42 |
| 50-HB-400 | 1230 | 292 | 71 | 147 | 35 |
| 50-HB-660 | 1590 | 296 | 74 | 127 | 18 |
| 50-HB-2000 | 2660 | 300 | 90 | 116 | 23 |
| 75-H-1400 | 2470 | 294 | 34 | 115 | 41 |
| 75-H-9500 | 6950 | 280 | 79 | 98 | 11 |
| 75-H-90000 | 12000 | 253 | 167 | 77 | 8 |

While certain embodiments have been illustrated and described, it should be understood that changes and modifications can be made therein in accordance with ordinary skill in the art without departing from the technology in its broader aspects as defined in the following claims. Other embodiments are set forth in the following claims.

What is claimed is:

1. A chemical mechanical polishing (CMP) composition for polishing an object having a layer comprising cobalt and low-K material, comprising a complexor, an oxidizer, an abrasive, a cobalt corrosion inhibitor and an ILD suppressor,
wherein the ILD suppressor is a compound of the following formula: 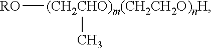
where
m is % propylene oxide (PO) by weight, and is 20% to 60% by weight of the total PO and EO units,
n is % ethylene oxide (EO) by weight, and is 40% to 80% by weight of the total PO and EO units,
R is a C₂₋₇alkyl, and
a weight ratio of EO to PO (EO:PO) is 2:3 to 4:1.

2. The CMP composition according to claim 1, wherein R is a C₂₋₄alkyl.

3. The CMP composition according to claim 1, wherein a molecular weight of the ILD suppressor is greater than 1,400.

4. The CMP composition according to claim 1, wherein a concentration of ILD suppressor in the slurry is greater than 0.07 wt. %.

5. The CMP composition according to claim 4, wherein a molecular weight of the ILD suppressor is greater than 1,000.

6. The CMP composition according to claim 1, wherein the weight ratio of EO to PO is 1:1 to 3:1.

7. The CMP composition according to claim 1, wherein m is 25% to 50% and n is 50% to 75%.

8. A method of selectively removing cobalt from a surface in the presence of one or more low-K material during a chemical mechanical polishing (CMP) process, comprising contacting the surface with a polishing pad; delivering a CMP composition according to claim 1 to the surface; and polishing said surface with the polishing slurry.

9. The method of claim 8, wherein the cobalt removal rate is greater than 1000 Å/min, and the low-K material removal rate is less than 5 Å/min.

10. The method of claim 8, wherein the selectivity (cobalt removal rate to low-K material removal rate) is greater than 2000.

11. A chemical mechanical polishing (CMP) composition for polishing an object having a layer comprising (1) a metal and/or a silicate material and (2) a low-K material, comprising a complexor, an oxidizer, an abrasive, a corrosion inhibitor, and a non-ionic surfactant comprising polyalkylene glycol groups of ethylene oxide or propylene oxide or a combination of both and no other functional groups, wherein a molecular weight of the non-ionic surfactant is about 1,000 to about 12,000 g/mol.

12. The CMP composition according to claim 11, wherein the surfactant is a polyalkylene glycol alkyl ether.

13. The CMP composition according to claim 11, wherein the pH is between 9 and 11.

14. The CMP composition according to claim 11, wherein the corrosion inhibitor contains an azole compound.

15. CMP composition according to claim 11, wherein the non-ionic surfactant is a compound of the following formula: 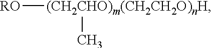
where
m is % propylene oxide (PO) by weight, and is 20% to 60% by weight of the total PO and EO units,
n is % ethylene oxide (EO) by weight, and is 40% to 80% by weight of the total PO and EO units,
R is a C₂₋₇alkyl, and
a weight ratio of EO to PO (EO:PO) is 2:3 to 4:1.

16. The CMP composition according to claim 15, wherein R is a C₂₋₄alkyl.

17. The CMP composition according to claim 11, wherein the molecular weight of the non-ionic surfactant is greater than 2,000 g/mol.

18. The CMP composition according to claim 11, wherein the molecular weight of the non-ionic surfactant is greater than 2,600 g/mol.

19. The CMP composition according to claim 11, wherein the metal and/or silicate material is selected from the group consisting of tantalum, copper, TEOS, and combinations thereof.

20. A method of selectively removing tantalum, copper, and/or TEOS from a surface in the presence of one or more low-K materials during a chemical mechanical polishing (CMP) process, comprising contacting the surface with a polishing pad; delivering a CMP composition according to claim 11 to the surface; and polishing said surface with the CMP composition.

21. The method of claim 20, wherein the tantalum, copper, and/or TEOS removal rate is greater than 200 Å/min, and the low-K material removal rate is less than 70 Å/min.

22. The method of claim 21, wherein the surface comprises tantalum, and the removal rate is greater than 400 Å/min.

23. The method of claim 21, wherein the surface comprises copper, and the removal rate is greater than 200 Å/min.

24. The method of claim 21, wherein the surface comprises TEOS, and the removal rate is greater than 200 Å/min.

25. A CMP composition according to claim 1, wherein the composition also polishes an object having a layer comprising tantalum, copper, and/or TEOS and a low-K material.

26. The method according to claim 8, wherein the method selectively removes tantalum, copper, and/or TEOS from a surface in the presence of one or more low-K materials during a chemical mechanical polishing (CMP) process.
